(19) United States
(12) Patent Application Publication
(10) Pub. No.: US 2020/0271704 A1
(43) Pub. Date: Aug. 27, 2020

(54) APPARATUS AND METHOD FOR MONITORING WIRELESS POWER TRANSMITTER

(71) Applicant: Maps, Inc., Seoul (KR)

(72) Inventors: Jong Tae HWANG, Seoul (KR); Hyun Ick SHIN, Seoul (KR); Sang-O JEON, Suwon-si (KR); Ik-Gyoo SONG, Incheon (KR); Ik Soo JEON, Yongin-si (KR); Joon RHEE, Seoul (KR)

(73) Assignee: Maps, Inc., Seoul (KR)

(21) Appl. No.: 16/092,312

(22) PCT Filed: Apr. 7, 2017
(86) PCT No.: PCT/KR2017/003798

§ 371 Date: Oct. 9, 2018

(30) Foreign Application Priority Data
Apr. 14, 2016 (KR) 10-2016-0045756
Apr. 19, 2016 (KR) 10-2016-0047350
Jun. 14, 2016 (KR) 10-2016-0073758

(51) Int. Cl. G01R 21/06; G01R 19/165; G01R 25/00; G01R 27/26; G05F 1/56; G01R 19/25; G01R 21/133

(52) U.S. Cl. CPC G01R 21/06; G01R 19/16566; G01R 25/00; G01R 21/133; G01R 27/2611; G05F 1/56; G01R 19/25; G01R 27/2605

(57) ABSTRACT

Provided are an apparatus and method for monitoring a wireless power transmitter. The apparatus for monitoring the wireless power transmitter includes a magnitude information detector included in a resonator of the wireless power transmitter and configured to detect magnitude information of voltages at opposite ends of an impedance device connected to the resonator, a phase difference detector configured to detect phase difference information of the voltages at the opposite ends of the impedance device, and a controller configured to monitor a state of the resonator on the basis of the magnitude information of the voltages at the opposite ends of the impedance device and the phase difference information, which are detected by the magnitude information detector and the phase difference detector.

### TECHNICAL FIELD

The present invention relates to wireless power transmitting and receiving technology.

### BACKGROUND ART

Many techniques have been developed to transmit power wirelessly. As representative examples of such techniques, there are an electric wave reception technique using microwaves, a magnetic induction technique using a magnetic field, a magnetic resonance technique using energy conversion between a magnetic field and an electric field, etc.

A wireless power transmitter may identify an efficiency of a resonator, a power transmission state, and a state of a wireless power receiver by monitoring a state of the resonator which includes a capacitor and an antenna. The state of the resonator may be identified by measuring an input voltage, an input current, an input impedance, and active power of the resonator.

However, when power is wirelessly transmitting at a high frequency of 6.78 MHz as in an Alliance for Wireless Power (A4WP) method, it is not easy to measure the four parameters described above in a general manner because the frequency is very fast and a voltage of the resonator is high.

### DISCLOSURE

### Technical Problem

In an embodiment, an apparatus and method for monitoring a wireless power transmitter which transmits power wirelessly are proposed.

### Technical Solution

One aspect of the present invention provides an apparatus for monitoring a wireless power transmitter, the apparatus including a magnitude information detector included in a resonator of the wireless power transmitter and configured to detect magnitude information of voltages at opposite ends of an impedance device connected to the resonator; a phase difference detector configured to detect phase difference information of the voltages at the opposite ends of the impedance device; and a controller configured to monitor a state of the resonator on the basis of the magnitude information of the voltages at the opposite ends of the impedance device and the phase difference information, which are detected by the magnitude information detector and the phase difference detector.

The impedance device may include a resistor, an inductor, a capacitor, or a combination thereof.

The magnitude information detector may include a transformer configured to generate voltages v1x and v2x with respect to a first input voltage signal V1 formed between a voltage V1p at one end of a first impedance device and a voltage V1n at one end of a second impedance device and a second input voltage signal V2 formed between a voltage V2p at another end of the first impedance device and a voltage V2n at another end of the second impedance device, the voltages v1x and v2x swinging from a ground voltage; and a peak detector configured to detect peak values of the respective voltages v1x and v2x output from the transformer. The magnitude information detector may further include a first voltage regulator configured to control gains of the voltages at the opposite ends of each of the first and second impedance devices and transmit the gain-controlled voltages to the transformer; and a second voltage regulator configured to control the gains of the voltages by receiving output voltages having the peak values from the peak detector. Magnitude information |V1| of the first input voltage V1 may be a product of a gain K1 of the first voltage regulator, a gain K2 of the second voltage regulator, and a voltage difference |V1p−V1n| between the voltage V1p at the one end of the first impedance device and the voltage V1n at the one end of the second impedance device, and magnitude information |V2| of the second input voltage V2 may be a product of the gain K1 of the first voltage regulator, the gain K2 of the second voltage regulator, and a voltage difference |V2p−V2n| between the voltage V2p at the other end of the first impedance device and the voltage V2n at the other end of the second impedance device.

The phase difference detector may include a capacitor configured to remove direct-current (DC) components from the voltages v1x and v2x output from the transformer; a first voltage comparator configured to receive an output voltage of the capacitor with respect to the first input voltage signal V1 and a ground voltage and compare the output voltage with the ground voltage; a second voltage comparator configured to receive an output voltage of the capacitor with respect to the second input voltage signal V2 and the ground voltage and compare the output voltage with the ground voltage; and a phase difference comparator configured to receive an output voltage of the first voltage comparator and an output voltage of the second voltage comparator and compare a phase difference between the output voltages. The phase difference detector may further include an inversion amplifier configured to receive an output of the phase difference comparator, allow the output to pass through a low-pass band, and amplify a signal obtained when the output passes through the low-pass band. The phase difference comparator may output a voltage signal linearly changing according to a phase difference between the output voltage of the first voltage comparator and the output voltage of the second voltage comparator.

The controller may measure at least one among an input voltage, an input current, an input impedance, and active power of the resonator on the basis of the magnitude information of the voltages at the opposite ends of the impedance device and the phase difference information, which are detected by the magnitude information detector and the phase difference detector. The controller may calculate an input current of the impedance device on the basis of the magnitude information of the voltages at the opposite ends of the impedance device and the phase difference information and calculate a phase of the input current on the basis of the calculated input current. The controller may calculate an input impedance and active power on the basis of magnitude information of an input voltage at one end of the impedance device, an input current, and information regarding a phase of the input current.

The controller may control an amount of power to be transmitted to a wireless power receiver by controlling the resonator or the power amplifier on the basis of a result of monitoring the state of the resonator.

### Advantageous Effects

In one embodiment, a state of a resonator of a wireless power transmitter can be monitored. Particularly, the wireless power transmitter which transmits power wirelessly at a high frequency can be monitored. An input voltage, an input current, an input impedance, and active power of the resonator included in the wireless power transmitter can be effectively measured. Accordingly, an efficiency of the resonator and a power transmission state can be identified. Furthermore, a reception environment of a wireless power receiver may be identified.

### DESCRIPTION OF DRAWINGS

FIG. 1 is a diagram illustrating a structure of a wireless power system to which the present invention is applied,

FIG. 2 is a conceptual diagram of an apparatus which monitors a wireless power transmitter (hereinafter referred to as the ‘monitoring apparatus’) according to an embodiment of the present invention,

FIG. 3 is a circuit diagram of the monitoring apparatus of FIG. 2 according to an embodiment of the present invention,

FIG. 4 is a circuit diagram of a phase difference comparator of FIG. 3 according to an embodiment of the present invention,

FIG. 5 is a graph showing a signal output via a phase difference comparator according to an embodiment of the present invention,

FIG. 6 is a diagram illustrating a structure of a resonator to explain a structure of a monitoring apparatus according to another embodiment of the present invention,

FIG. 7 is a circuit diagram of the monitoring apparatus of FIG. 6 according to another embodiment of present invention, and

FIG. 8 is a diagram illustrating a structure of a monitoring apparatus according to still another embodiment of the present invention.

### MODES OF THE INVENTION

Advantages and features of the present invention and methods of achieving them will be apparent from embodiments which will be described in detail in conjunction with the accompanying drawings. However, the present invention is not limited thereto and may be embodied in many different forms. These embodiments are merely provided so that this disclosure will be thorough and complete and will fully convey the concept of the invention to those of ordinary skill in the art. The present invention should be defined by the claims only. In the drawings, the same reference numerals represent the same elements throughout the drawings.

When embodiments of the present invention are described, well-known functions or constructions are not described in detail if it is determined that they would obscure the invention due to unnecessary detail. Terms which will be described below are defined in consideration of functions in embodiments of the present invention and thus may be defined differently according to a user or operator's intention, precedents, or the like. Accordingly, the terms used herein should be defined on the basis of the whole context of the present invention.

Each block of block diagrams and combination of operations of a flowchart in the accompanying drawings may be performed by computer program instructions (execution engines) which may be stored in a processor of a general-purpose computer, a special-purpose computer, or another type of programmable data processing equipment. Thus, means for performing functions described in the blocks of the block diagrams or the operations of the flowchart are produced from the program instructions that are executed through the processor of a computer or another type of programmable data processing equipment.

The computer program instructions may be stored in a computer usable or readable memory available in a computer or another type of programmable data processing equipment to implement functions in a specific manner. Thus, products including instruction means for performing the functions described in the blocks of the block diagrams or the operations of the flowchart may be produced through the instructions stored in the computer usable or readable memory.

Furthermore, the computer program instructions may be loaded into a computer or another type of programmable data processing equipment so that a series of operations may be performed in the computer or the other type of programmable data processing equipment to create a computer executable process. Thus, the instructions for executing the computer or the other data type of programmable processing equipment may provide operations for performing the functions described in the blocks of the block diagrams and the operations of the flowchart.

In addition, each block or operation may represent a module, a segment, or a part of code that includes one or more executable instructions for executing specified logical functions. In some alternative embodiments, functions specified in blocks or operations may be performed in a different order. For example, two successive blocks or operations may actually be performed substantially concurrently or may be performed in a reverse order if necessary.

Hereinafter, embodiments of the present invention will be described in detail with reference to the accompanying drawings. However, various changes may be made in the following embodiments of the present invention, and the scope of the present invention is not limited by the following embodiments. These embodiments of the present invention are provided to help understanding of the present invention by those of ordinary skill in the art.

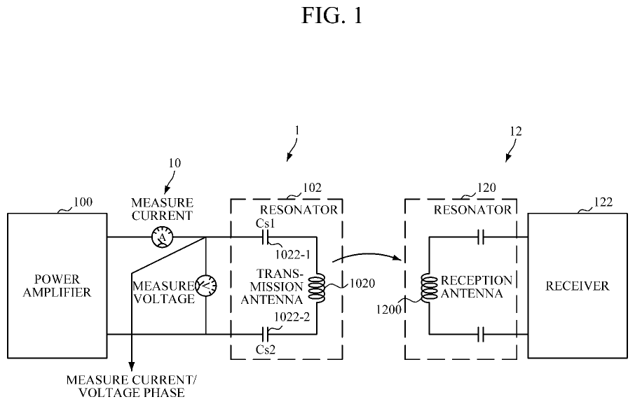

FIG. 1 is a diagram illustrating a structure of a wireless power system to which the present invention is applied.

Referring to FIG. 1, a wireless power system 1 includes a power transmitting unit (PTU) 10 and a power receiving unit (PRU) 12.

The PTU 10 largely includes a power amplifier 100 and a resonator 102. The resonator 102 includes a transmission antenna 1020, a first capacitor Cs1 1022-1, and a second capacitor Cs2 1022-2 and transmits a wireless power signal to the PRU 12 using a resonance frequency determined by the transmission antenna 1020, the first capacitor Cs1 1022-1, and the second capacitor Cs2 1022-2. The power amplifier 100 outputs an alternating-current (AC) voltage/current of a frequency corresponding to the resonance frequency of the resonator 102 so as to drive the resonator 102. Actually, since an electro-magnetic-interference (EMI) filter or the like is connected to an output of the power amplifier 100, an output voltage/current of the power amplifier 100 is not exactly the same as a voltage/current of the resonator 102. The PRU 12 includes a resonator 120 and a receiver 122 which is configured to convert AC power received from the resonator 120 into direct-current (DC) power.

Wireless power transmission is performed through sharing a magnetic field between the transmission antenna 1020 of the PTU 10 and a reception antenna 1200 of the PRU 12. Thus, the two antennae 1020 and 1200 may be considered as being equivalent to transformers. Thus, an impedance of the resonator 102 of the PTU 10 changes according to a state of a load on the PRU 12 or when the PRU 12 is not provided and a conductive object such as a metal is located near the transmission antenna 1020 of the PTU 10. Accordingly, the state of the PRU 12 may be indirectly identified by calculating an input voltage/current of the resonator 102 of the PTU 10 and information regarding a phase of the resonator 102. Furthermore, the power amplifier 100 may be controlled to be stably operated on the basis of the efficiency and state of the resonator 102. Accordingly, it is very important to monitor the state of the resonator 102. For example, an input voltage, an input current, a phase, and active power of the resonator 102 need to be measured.

A voltage/current of the resonator 102 is generally in an AC form and a frequency thereof is not particularly limited. In the Alliance for Wireless Power (A4WP) method, a frequency of 6.78 MHz is used and thus a voltage/current of the resonator 102 has a frequency of 6.78 MHz. In the A4WP method, a high frequency is used and thus a current is not easy to measure by a general method. A voltage of the resonator 102 varies according to power supplied from the power amplifier 100 and characteristics of a load thereon but may be generally increased to several hundreds of volts. Thus, there are difficulties measuring a high-voltage signal changing at high speeds. In particular, it is very difficult to measure a current.

When an existing sensing resistor is used to measure a current, power consumption is high. Furthermore, it is very difficult to implement a differential amplifier which measures voltages at opposite ends of a resistor operated with a high voltage. Thus, a method of measuring a current using a resistor is not preferable. As another method, a current transformer may be used. This method is also feasible but a current transformer through which a large amount of current flows and which is capable of measuring 6.78 MHz current is not easy to form. In particular, when a large amount of current flows, the transformer may be saturated and thus a large error may occur in a measurement result.

In the present invention, information regarding voltages at opposite ends of an impedance device of a resonator and a phase difference between the voltages is obtained, and a state of the resonator is monitored on the basis of this information. n this case, the state of the resonator may be monitored by measuring at least one among an input voltage, an input current, an input impedance, and active power of the resonator.

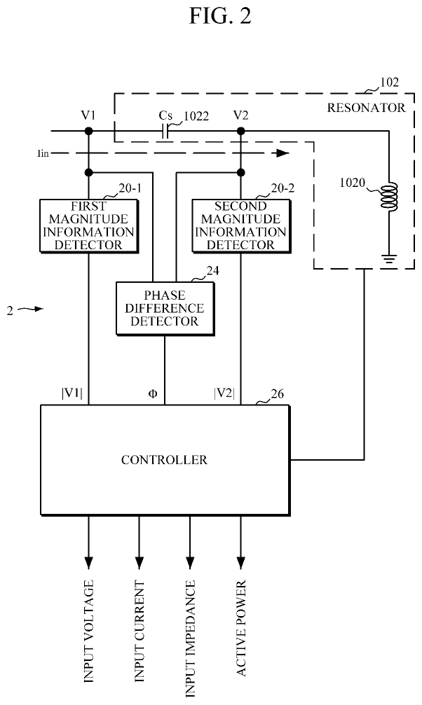

FIG. 2 is a conceptual diagram of an apparatus which monitors a wireless power transmitter (hereinafter referred to as the ‘monitoring apparatus’) according to an embodiment of the present invention.

Referring to FIG. 2, a monitoring apparatus 2 includes two magnitude information detectors 20-1 and 20-2, a phase difference detector 24, and a controller 26.

The monitoring apparatus 2 obtains magnitude information |V1| and |V2| of voltages V1 and V2 at opposite ends of an impedance device Zs of a resonator by using the two magnitude information detectors 20-1 and 20-2 and obtains phase difference information ø (phi) between the voltages V1 and V2 at the opposite ends of the impedance device Zs through the phase difference detector 24. The impedance device Zs may be included in or connected to a resonator 102 of the wireless power transmitter. In FIG. 2, a case in which the impedance device Zs is included in the resonator 102 will be described as an example below. The impedance device Zs may include a resistor Rs, an inductor Ls, a capacitor Cs, or a combination thereof. In FIG. 2, a case in which the impedance device Zs is the capacitor Cs will be described below.

The controller 26 monitors a state of the resonator 102 on the basis of the magnitude information |V1| and |V2| of the voltages V1 and V2 at the opposite ends of the impedance device Zs and the phase difference information ø, which are obtained by the two magnitude information detectors 20-1 and 20-2 and the phase difference detector 24. For example, an input voltage, an input current, an input impedance, and active power of the resonator 102 may be identified. The controller 26 calculates the input current of the resonator 102 on the basis of the magnitude information |V1| and |V2| of the voltages V1 and V2 at the opposite ends of the impedance device Zs and the phase difference information ø and calculates a phase of the input current on the basis of the calculated input current. The controller 26 calculates the input impedance and the active power of the resonator 102 on the basis of the magnitude information |V1| or |V2| of the voltage V1 or V2 at one end of the impedance device Zs, the input current, and the phase of the input current. The controller 26 may be, for example, a microcontroller (Micom).

In an embodiment, the controller 26 identifies a state of a wireless power receiver on the basis of a result of monitoring the state of the resonator 102 and controls the amount of power to be transmitted to the wireless power receiver by controlling the resonator 102 or the power amplifier 100 according to the state of the wireless power receiver.

An example in which input-voltage magnitude information |V1| and |V2| and phase difference information ø are calculated when the impedance device Zs is the capacitor Cs 1022 will be described with reference to FIG. 2 below. The input-voltage information |V1| and |V2| of input voltages V1 and V2 at opposite ends of the resonator capacitor Cs 1022 are calculated using the magnitude information detectors 20-1 and 20-2. Next, a phase difference between the input voltages V1 and V2 is calculated using the phase difference detector 24 configured to compare phases of input voltages V1 and V2. In this case, a phase difference of the input voltage V2 relative to a phase of the input voltage V1 may be calculated. A result of calculating the phase difference of the input voltage V2 relative to the phase of the input voltage V1 is ø. The input voltage, the input current, the input impedance, and the active power of the resonator 102 are appropriately calculated by the controller 26 on the basis of three types of information |V1|, |V2|, and ø.

A method of measuring the input current of the resonator 102 using the following equations on the basis of the input-voltage magnitude information |V1| and |V2| and the phase difference information ø will be described below. The input voltages V1 and V2 when the phase of the input voltage V1 is a reference phase may be expressed by Euler's formula as shown in Equations 1 and 2 below. In this case, it is assumed that the phase of the input voltage V2 is shifted by ø relative to the

input voltage V1.

V1=|V1|e^{jO} [symbol] Equation 1

[symbol]

V2=|V2|e^{jΦ} [symbol] Equation 2

[symbol]

An input current Iin of the capacitor Cs satisfies Equation 3 below.

Iin=sCs(|V1|e^{jO}=|V2|e^{jΦ} [symbol] Equation 3

[symbol]

Equation 3 above may be expressed as Equation 4 below.

Iin=sCs(|V1|−|V2|cos Φ−j|V2|sin Φ) [symbol] Equation 4

[symbol]

In Equation 4, a magnitude |Iin| of the input current Iin may be calculated by Equation 5 below.

$$\vert Iin \vert = ω Cs \sqrt{{( \vert V 1 \vert - \vert V 2 \vert cos Φ )}^{2} + {\vert V 2 \vert}^{2} {sin}^{2} Φ} = ω Cs \sqrt{{\vert V 1 \vert}^{2} + {\vert V 2 \vert}^{2} - 2 \vert V 1 \vert \vert V 2 \vert cos Φ} \qquad [ Equation 5 ]$$

In Equation 5, ω=2π×6.78 MHz.

A phase θ (theta) of the input current Iin may be calculated by Equation 6 below.

$$phase ( Iin ) = θ = {tan}^{- 1} ( \frac{\vert V 1 \vert - \vert V 2 \vert cos Φ}{\vert V 2 \vert sin Φ} ) \qquad [ Equation 6 ]$$

It can be seen that information regarding the input current Iin is completely obtained from an expansion of the equations above. The input impedance Zin of the resonator 102 may be calculated by the above equations. The input impedance Zin may be calculated by Equation 7 below.

$$Zin = \frac{\vert V 1 \vert}{\vert Iin \vert {e}^{j θ}} = \frac{\vert V 1 \vert}{\vert Iin \vert} ( cos θ - j sin θ ) \qquad [ Equation 7 ]$$

As shown n Equation 7, a complex-form result may be obtained, in which a real-number part represents a resistance component R and an imaginary-number part represents a reactance component X.

Active power Pin of the resonator 102 may be calculated by Equation 8 below on the basis of the phase θ (theta) of the input current Iin calculated by

Pin=|V1||Iin|cos θ [symbol] Equation 8

[symbol]

In conclusion, all desired information may be calculated on the basis of the magnitude information |V1| and |V2| and the phase difference information ø.

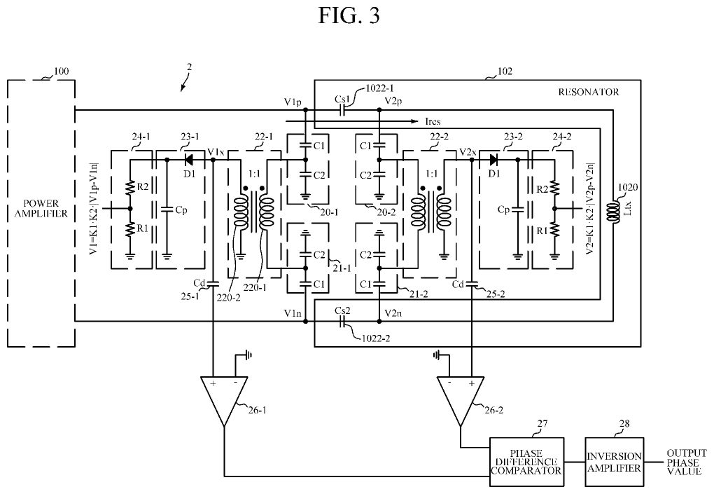

FIG. 3 is a circuit diagram of the monitoring apparatus 2 of FIG. 2 according to an embodiment of the present invention.

Referring to FIGS. 2 and 3, when the impedance device Zs of the resonator 102 includes a first capacitor Cs1 1022-1 and a second capacitor Cs2 1022-2, a first magnitude information detector 20-1 which detects magnitude information |V1| of an input voltage V1 includes first V1 voltage regulators 20-1 and 21-1, a V1 transformer 22-1, a V1 peak detector 23-1, and a second V1 voltage regulator 24-1. Similarly, the second magnitude information detector 20-2 which detects magnitude information |V2| of an input voltage V2 includes first V2 voltage regulators 20-2 and 21-2, a V2 transformer 22-2, a V2 peak detector 23-2, and a second V2 voltage regulator 24-2.

The components of the first magnitude information detector 20-1 will now be described. The first V1 voltage regulators 20-1 and 21-1 respectively control a gain of a voltage V1p at one end of the first capacitor Cs1 1022-1 and a gain of a voltage V1n at one end of the second capacitor Cs2 1022-2. For example, since the voltages V1p and V1n may be very high, the voltages V1p and V1n are converted into lower voltages through the first V1 voltage regulators 20-1 and 21-1. To this end, the first V1 voltage regulators 20-1 and 21-1 may use the capacitors C1 and C2.

The V1 transformer 22-1 receives the voltages obtained through the conversion by the first V1 voltage regulators 20-1 and 21-1, generates a voltage signal v1x swing from a ground voltage, and outputs the voltage signal v1x. The V1 transformer 22-1 may include two inductors 220-1 and 220-2 at a ratio of 1:1. The ratio of 1:1 may be understood to mean that the number of power lines of the primary inductor 220-1 and the number of power lines of the secondary inductor 220-2 which are coupled to each other are the same. The primary inductor 220-1 is connected to outputs of the first voltage regulators 20-1 and 21-1. One end of the secondary inductor 220-2 is connected to an output terminal and another end thereof s connected to a ground voltage source.

The V1 peak detector 23-1 detects a peak value of an output voltage v1x of the V1 transformer 22-1. The V1 peak detector 23-1 may include a diode D1 and a capacitor Cp. The detected peak value may be stored in the capacitor Cp.

The second V1 voltage regulator 24-1 is connected to the V1 peak detector 23-1 and controls a voltage gain of an output voltage having the peak value. For example, the second V1 voltage regulator 24-1 may reduce the peak value of the output voltage to a lower voltage value through resistors R1 and R2. The magnitude information |V1| of the input voltage V1 output via the second V1 voltage regulator 24-1 is a product of a gain K1 of the first V1 voltage regulators 20-1 and 21-1, a gain K2 of the second V1 voltage regulator 24-1, and a voltage difference (|V1p−V1n|) between a voltage V1p at one end of the first capacitor Cs1 1022-1 and a voltage V1n at one end of the second capacitor Cs2 1022-2.

The magnitude information |V2| of the input voltage V2 may be obtained by a method similar to the method of obtaining the magnitude information |V1| of the input voltage V1 described above. Therefore, the method is not described in detail here.

The phase difference detector 24 may include capacitors Cd 25-1 and 25-2, a first voltage comparator 26-1, a second voltage comparator 26-2, and a phase difference comparator 27 and may further include an inversion amplifier 28.

The V1 capacitor Cd 25-1 removes a DC component from an output voltage v1x of the V1 transformer 22-1. Similarly, the V2 capacitor Cd 25-2 removes a DC component from an output voltage v2x of the V2 transformer 22-2.

The first voltage comparator 26-1 receives and compares an output voltage of the V1 capacitor Cd 25-1 and a ground voltage. The second voltage comparator 26-2 receives and compares an output voltage of the V2 capacitor Cd 25-2 and the ground voltage. The phase difference comparator 27 receives an output voltage of the first voltage comparator 26-1 and an output voltage of the second voltage comparator 26-2 and compares a phase difference between the input voltages V1 and V2.

The inversion amplifier 28 receives an output of the phase difference comparator 27, allows the output to pass through a low-pass band, and amplifies a signal obtained when the output passes through the low-pass band. A signal output via the inversion amplifier 28 may be a voltage signal linearly changing according to a phase difference between the output voltage of the first voltage comparator 26-1 and an output voltage of the second voltage comparator 26-2.

A method of obtaining input-voltage magnitude information |V1| and |V2| and phase difference information ø of a resonator will be described with reference to the circuit diagram of FIG. 3 below.

As illustrated in FIG. 3, when the resonator 102 includes the two capacitors Cs1 1022-1 and Cs2 1022-2, the input-voltage magnitude information |V1| and |V2| of the resonator 102 is obtained. The voltages V1p, V1n, V2p, and V2n may be very high voltages. Thus, the voltages V1p, V1n, V2p, and V2n are converted into appropriately low voltages through the first voltage regulators 20-1, 20-2, 21-1, and 21-2 and the capacitors C1 and C2. In this case, gains K1 of the first voltage regulators 20-1, 20-2, 21-1, and 21-2 may be calculated by Equation 9 below.

$$K 1 = \frac{C 1}{C 1 + C 2} \qquad [ Equation 9 ]$$

A signal swing from the ground voltage is generated from a voltage reduced by the gain K1 by using the transformers 22-1 and 22-2. In this case, output voltages of the transformers 22-1 and 22-2 are expressed by Equation 10 below.

V1x=K1(V1p−V1n), V2x=K1(V2p−V2n) [symbol] Equation 10

[symbol]

Peak values are detected with respect to the voltage signals V1x and V2x by the peak detectors 23-1 and 23-2 each including the diode D1 and the capacitor Cp. Thus, the peak values of the voltage signals V1x and V2x are stored in the capacitor Cp. When the gain K2 is reduced by the second voltage regulators 24-1 and 24-2 each including the resistors R1 and R2, the magnitude information |V1| and |V2| of the input voltages V1 and V2 as expressed by Equation 11 below is finally obtained.

|V1|=K1K2|V1p−V1n|, |V2|=K1K2|V2p−V2n| [symbol] Equation 11

[symbol]

The capacitors Cd 25-1 and 25-2 located at points, at which the transformers 22-1 and 22-2 and the peak detectors 23-1 and 23-2 are connected, are connected to inputs of the voltage comparators 26-1 and 26-2, respectively. Since remaining DC components are completely removed by the capacitors Cd 25-1 and 25-2, (+) inputs of the voltage comparators 26-1 and 26-2 are signals swinging from 0 volts. Outputs of the voltage comparators 26-1 and 26-2 are at a high level when the (+) inputs of the voltage comparators 26-1 and 26-2 are greater ha zero, and are 0 volts when the (+) inputs of the voltage comparators 26-1 and 26-2 are equal to or less than zero. Accordingly, the outputs of the voltage comparators 26-1 and 26-2 are square-wave digital signals.

Rising edges of output signals of the voltage comparators 26-1 and 26-2 occur when the voltages V1 and V2 start to increase from zero. That is, rising edge signals contain phase information. When the outputs of the voltage comparators 26-1 and 26-2 are input to the phase difference comparator 27, the phase information may be electrically changed. Finally, when an output of the phase difference comparator 27 passes through the inversion amplifier 28 having a low-pass filter function, an analog signal linearly changing according to a phase difference may be obtained.

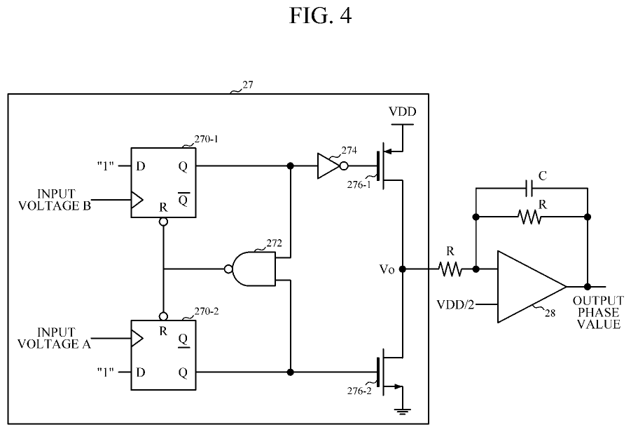

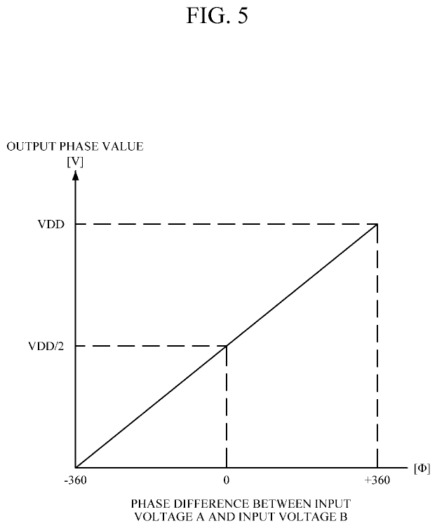

FIG. 4 is a circuit diagram of the phase difference comparator 27 of FIG. 3 according to an embodiment of the present invention. FIG. 5 is a graph showing a signal output via a phase difference comparator according to an embodiment of the present invention,

Referring to FIG. 4, the phase difference comparator 27 may include two D-flip-flops 270-1 and 270-2, a NAND block 272, an inverter 274, an NMOS transistor 276-1, and a PMOS transistor 276-2, and may further include an inversion amplifier 28.

In the D flip-flop DFF1 270-1, when 1 is input to a data input terminal D and an input voltage B is input to a clock input terminal T, 1 is output from an output terminal Q. The output of the output terminal Q of the D flip-flop DFF1 270-1 is input to the inverter 274, and the inverter 274 inverts the output and outputs a result of inverting the output. The output of the inverter 274 is supplied to the NMOS transistor 276-1. In the D flip-flop DFF2 270-2, when 1 is input to a data input terminal D and an input voltage A is input to a clock input terminal T, 1 is output from an output terminal Q. The output of the output terminal Q of the D flip-flop DFF2 270-2 is supplied to the PMOS transistor 276-2.

The NAND block 272 receives the output of the D flip-flop DFF1 270-1 and the output of the D flip-flop DFF2 270-2, outputs an output according to a NAND circuit, and inputs the output to a reset input terminal of the D flip-flop DFF1 270-1 and a reset input terminal of the DFF2 270-2.

An output voltage Vo of the phase difference comparator 27 has a high impedance value when the input voltage A and the input voltage B have the same phase. When the phase of the input voltage B is leading, the PMOS transistor 276-2 is turned on. In contrast, when the phase of the input voltage A is leading, the NMOS transistor 276-1 is turned on. Accordingly, a maximum value of the output voltage Vo is VDD, and a minimum value thereof is 0.

If the output voltage Vo is amplified by the inversion amplifier 28 having a loss-pass filter function and embodied as an operational amplifier, a voltage output may be generated according to a phase difference between the input voltage A and the input voltage B such that the VDD voltage is maximally output when the phase difference is 360 degrees and 0 volts are output when the phase difference is −360 degrees. Accordingly, as illustrated in FIG. 5, a voltage linearly changing according to the phase difference between the input voltage A and the input voltage B may be generated and thus phase difference information ø may be identified using the voltage. Finally, an input voltage, an input current, an input impedance, and active power of a resonator may be identified by the controller 26 on the basis of the input-voltage magnitude information |V1| and |V2| and the phase difference information ø.

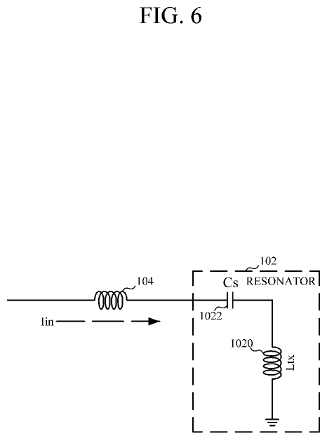

FIG. 6 is a diagram illustrating a structure of a resonator to explain a structure of a monitoring apparatus according to another embodiment of the present invention.

Although the method of monitoring a state of the resonator 102 by using the capacitor Cs has been described above with reference to FIG. 3, the state of the resonator 102 may be monitored using an inductor Ls 104 as illustrated in FIG. 6. The resonator 102 may be operated as an inductive load for zero-voltage switching according to a type of a power amplifier. In this case, as illustrated in FIG. 6, the inductor Ls 104 may be inserted to be in series with the resonator 102. In this case, an input current, a phase of the input current, an input impedance, and active power of the resonator 102 may be measured using the inductor Ls 104.

When the inductor Ls 104 is used, an input current Iin may be expressed by Equation 12 below.

$$Iin = \frac{( \vert V 1 \vert {e}^{j 0} - \vert V 2 \vert {e}^{j Φ} )}{sLs} \qquad [ Equation 12 ]$$

In this case, an input-current magnitude |Iin| may be calculated by Equation 13 below.

$$\vert Iin \vert = \frac{\sqrt{{( \vert V 1 \vert - \vert V 2 \vert cos Φ )}^{2} + {\vert V 2 \vert}^{2} {sin}^{2} Φ}}{ω Ls} = \frac{\sqrt{{\vert V 1 \vert}^{2} + {\vert V 2 \vert}^{2} - 2 \vert V 1 \vert \vert V 2 \vert cos Φ}}{ω Ls} \qquad [ Equation 13 ]$$

A phase θ of the input current Iin may be expressed by Equation 14 below.

$$phase ( Iin ) = θ = {tan}^{- 1} ( \frac{- \vert V 1 \vert + \vert V 2 \vert cos Φ}{\vert V 2 \vert sin Φ} ) \qquad [ Equation 14 ]$$

In this case, an equation of the input impedance may be changed to an equation of V2, i.e., Equation 15 below.

$$Zin = \frac{\vert V 2 \vert}{\vert Iin \vert {e}^{j θ}} = \frac{\vert V 2 \vert}{\vert Iin \vert} ( cos θ - j sin θ ) \qquad [ Equation 15 ]$$

Similarly, an equation of the active power may be changed to an equation of V2, i.e., Equation 16 below.

Pin=|V2||Iin|cos θ [symbol] Equation 16

[symbol]

In conclusion, all desired information may be calculated using the input-voltage information |V1| and |V2| and the phase difference information ø.

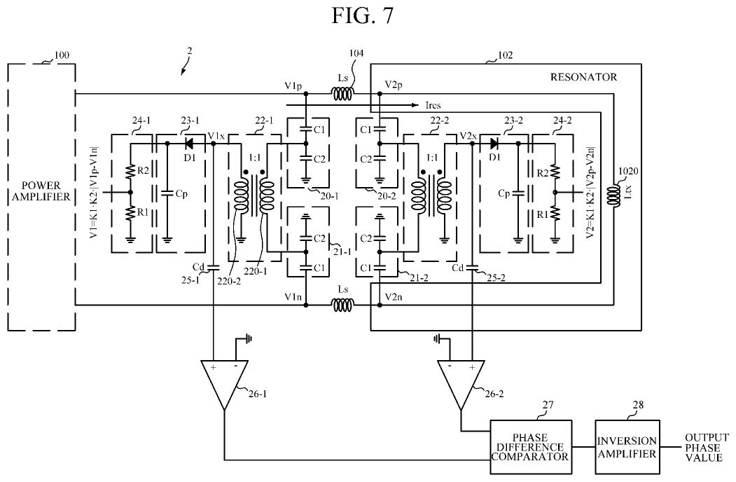

FIG. 7 is a circuit diagram of the monitoring apparatus of FIG. 6 according to another embodiment of present invention.

A circuit of FIG. 7 has the same construction as that of FIG. 3 except that the inductor Ls 104 is added. A method of obtaining input-voltage magnitude information |V1| and |V2| and phase difference information ø of the resonator 102 corresponds to that described above with reference to FIG. 3 and thus is not redundantly described here.

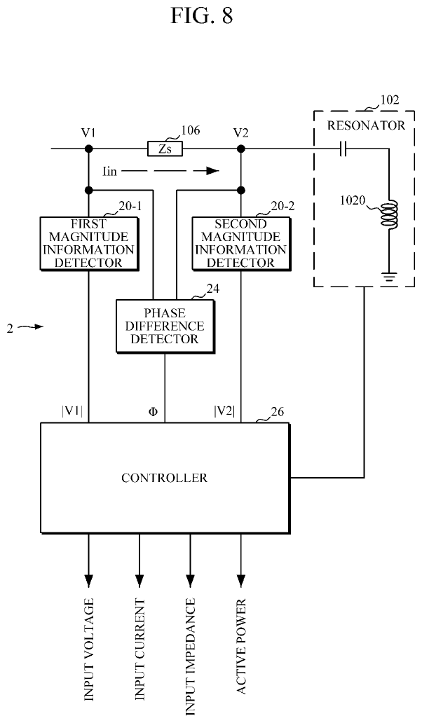

FIG. 8 is a diagram illustrating a structure of a monitoring apparatus according to another embodiment of the present invention.

Referring to FIG. 8, compared to FIG. 3, a state of a resonator 102 may be monitored using an impedance device Zs 106 instead of the capacitor Cs. For example, an input voltage, an input current, an input impedance, and active power of the resonator 102 may be calculated. In this case, although the above-described equations vary slightly, the state of the resonator 102 may be monitored using the impedance device Zs as described above with reference to FIG. 3. Alternatively, as illustrated in FIG. 2, the impedance device Zs may be included in the resonator 102.

The present invention has been described above with respect to embodiments thereof. It will be apparent to those of ordinary skill in the technical field to which the present invention pertains that the present invention may be embodied in different forms without departing from essential features thereof. Accordingly, the embodiments set forth herein should be considered in a descriptive sense only and not for purposes of limitation. The scope of the present invention is defined in the appended claims other than the above description, and all differences falling within the same range as the present invention should be understood as being included in the present invention.

1. An apparatus for monitoring a wireless power transmitter, comprising:
a magnitude information detector included in a resonator of the wireless power transmitter and configured to detect magnitude information of voltages at opposite ends of an impedance device connected to the resonator;
a phase difference detector configured to detect phase difference information of the voltages at the opposite ends of the impedance device; and
a controller configured to monitor a state of the resonator on the basis of the magnitude information of the voltages at the opposite ends of the impedance device and the phase difference information, which are detected by the magnitude information detector and the phase difference detector.

2. The apparatus of claim 1, wherein the impedance device comprises a resistor, an inductor, a capacitor, or a combination thereof.

3. The apparatus of claim 1, wherein the magnitude information detector comprises:
a transformer configured to generate voltages v1x and v2x with respect to a first input voltage signal V1 formed between a voltage V1p at one end of a first impedance device and a voltage V1n at one end of a second impedance device and a second input voltage signal V2 formed between a voltage V2p at another end of the first impedance device and a voltage V2n at another end of the second impedance device, the voltages v1x and v2x swinging from a ground voltage; and
a peak detector configured to detect peak values of the respective voltages v1x and v2x output from the transformer.

4. The apparatus of claim 3, wherein the magnitude information detector further comprises:
a first voltage regulator configured to control gains of the voltages at the opposite ends of each of the first and second impedance devices and transmit the gain-controlled voltages to the transformer; and
a second voltage regulator configured to control the gains of the voltages by receiving output voltages having the peak values from the peak detector.

5. The apparatus of claim 4, wherein magnitude information |V1| of the first input voltage V1 is a product of a gain K1 of the first voltage regulator, a gain K2 of the second voltage regulator, and a voltage difference |V1p−V1n| between the voltage V1p at the one end of the first impedance device and the voltage V1n at the one end of the second impedance device, and
magnitude information |V2| of the second input voltage V2 is a product of the gain K1 of the first voltage regulator, the gain K2 of the second voltage regulator, and a voltage difference |V2p−V2n| between the voltage V2p at the other end of the first impedance device and the voltage V2n at the other end of the second impedance device.

6. The apparatus of claim 4, wherein the phase difference detector comprises:
a capacitor configured to remove direct-current (DC) components from the voltages v1x and v2x output from the transformer;
a first voltage comparator configured to receive an output voltage of the capacitor with respect to the first input voltage signal V1 and a ground voltage and compare the output voltage with the ground voltage;
a second voltage comparator configured to receive an output voltage of the capacitor with respect to the second input voltage signal V2 and the ground voltage and compare the output voltage with the ground voltage; and
a phase difference comparator configured to receive an output voltage of the first voltage comparator and an output voltage of the second voltage comparator and compare a phase difference between the output voltages.

7. The apparatus of claim 6, wherein the phase difference detector further comprises an inversion amplifier configured to receive an output of the phase difference comparator, allow the output to pass through a low-pass band, and amplify a signal obtained when the output passes through the low-pass band.

8. The apparatus of claim 6, wherein the phase difference comparator outputs a voltage signal linearly changing according to a phase difference between the output voltage of the first voltage comparator and the output voltage of the second voltage comparator.

9. The apparatus of claim 1, wherein the controller measures at least one among an input voltage, an input current, an input impedance, and active power of the resonator on the basis of the magnitude information of the voltages at the opposite ends of the impedance device and the phase difference information, which are detected by the magnitude information detector and the phase difference detector.

10. The apparatus of claim 1, wherein the controller calculates an input current of the impedance device on the basis of the magnitude information of the voltages at the opposite ends of the impedance device and the phase difference information and calculates a phase of the input current on the basis of the calculated input current.

11. The apparatus of claim 1, wherein the controller calculates an input impedance and active power on the basis of magnitude information of an input voltage at one end of the impedance device, an input current, and information regarding a phase of the input current.

12. The apparatus of claim 1, wherein the controller controls an amount of power to be transmitted to a wireless power receiver by controlling the resonator or the power amplifier on the basis of a result of monitoring the state of the resonator.
